(19) United States
(12) Patent Application Publication
(10) Pub. No.: US 2024/0324393 A1
(43) Pub. Date: Sep. 26, 2024

(54) SENSOR-EMBEDDED DISPLAY PANEL AND ELECTRONIC DEVICE

(71) Applicant: Samsung Electronics Co., Ltd., Suwon-si (KR)

(72) Inventors: Sungyoung YUN, Suwon-si (KR); Kyung Bae PARK, Suwon-si (KR); Chul Joon HEO, Suwon-si (KR); Hwijoung SEO, Suwon-si (KR)

(73) Assignee: Samsung Electronics Co., Ltd., Suwon-si (KR)

(21) Appl. No.: 18/605,134

(22) Filed: Mar. 14, 2024

(30) Foreign Application Priority Data
Mar. 23, 2023 (KR) 10-2023-0037798

(51) Int. Cl. H10K 59/65; G06V 40/13; H10K 59/35; H10K 59/80; H10K 102/00

(52) U.S. Cl. CPC H10K 59/65; G06V 40/1318; H10K 59/353; H10K 59/80518; H10K 2102/351

(57) ABSTRACT

A sensor-embedded display panel includes a substrate, a plurality of light emitting elements on the substrate and configured to emit light of different wavelength spectra belonging to the visible light wavelength spectrum, and a plurality of sensors on the substrate and configured to selectively sense light of any one of a green wavelength spectrum and a red wavelength spectrum. Each of the sensors includes a photoelectric conversion layer that includes a first wavelength-selective photoelectric conversion material having a first maximum absorption wavelength in a wavelength range of about 500 nm to about 600 nm and a thickness of the buffer layer is about 20 nm to about 50 nm, or the photoelectric conversion layer includes a second wavelength-selective photoelectric conversion material having a second maximum absorption wavelength in a wavelength range of greater than about 600 nm and less than about 750 nm and a thickness of the buffer layer is about 70 nm to about 110 nm.

### CROSS-REFERENCE TO RELATED APPLICATION

This application claims priority to and the benefit of Korean Patent Application No. 10-2023-0037798 filed in the Korean Intellectual Property Office on Mar. 23, 2023, the entire contents of which are incorporated herein by reference.

### BACKGROUND

A sensor-embedded display panel and an electronic device are disclosed.

Recently, there is an increasing demand or desire for a display device implementing a biometric recognition technology that authenticates the person by extracting specific biometric information and/or behavioral characteristic information of a person with an automated device centering on finance, healthcare, or mobile field. Accordingly, the display device may include a sensor for biometric recognition.

### SUMMARY

Such a sensor for biometric recognition may be divided into an electrostatic type, an ultrasonic type, or an optical type. Among the various types, the optical type sensor is a sensor configured to absorb light and convert the absorbed light into an electrical signal. Organic material has a large extinction coefficient and may be configured to selectively absorb light in a particular wavelength region according to a molecular structure, and thus it may be usefully applied to the optical type sensor.

On the other hand, the sensor provided in the display device may be disposed under the display panel, or may be manufactured as a separate module and mounted on the outside of the display panel. However, when the sensor is disposed under the display panel, the object should be recognized through the display panel, various films, and/or other parts, and thus performance may be degraded. Alternatively when the sensor is manufactured and mounted as a separate module, there may be limitations in terms of design and/or usability. Accordingly, a sensor embedded in the display panel may be considered, but since the performance and/or physical properties required for each of the display panel and the sensor are different, it is difficult to implement both of them in an integrated form.

Various example embodiments provide a sensor-embedded display panel including a sensor capable of improving performance by being integrated with the display panel.

Alternatively or additionally, various example embodiments provide an electronic device including the sensor-embedded display panel.

According to some example embodiments, a sensor-embedded display panel includes a substrate, a plurality of light emitting elements on the substrate and configured to emit light of different wavelength spectra belonging to the visible light wavelength spectrum, and a plurality of sensors on the substrate and configured to selectively sense light of any one of a green wavelength spectrum and a red wavelength spectrum. The plurality of light emitting elements and the plurality of sensors are arranged in parallel along an in-plane direction of the substrate, the plurality of light emitting elements and the plurality of sensors include a common electrode configured to apply a common voltage, a first common auxiliary layer under the common electrode, and a second common auxiliary layer facing the first common auxiliary layer in common, each of the sensors includes a photoelectric conversion layer and a buffer layer between the first common auxiliary layer and the second common auxiliary layer, and the photoelectric conversion layer includes a first wavelength-selective photoelectric conversion material having a first maximum absorption wavelength in a wavelength range of greater than or equal to about 500 nm and less than or equal to about 600 nm and a thickness of the buffer layer is greater than or equal to about 20 nm and less than or equal to about 50 nm, and/or the photoelectric conversion layer includes a second wavelength-selective photoelectric conversion material having a second maximum absorption wavelength in a wavelength range of greater than about 600 nm and less than or equal to about 750 nm and a thickness of the buffer layer is greater than or equal to about 70 nm and less than or equal to 110 nm.

Alternatively or additionally, according to some example embodiments, a sensor-embedded display panel includes unit pixels repeatedly arranged, the unit pixels including at least one red subpixel configured to display red and including a red light emitting element, at least one green subpixel configured to display green and including a green light emitting element, at least one blue subpixel configured to display blue and including a blue light emitting element, and a sensor pixel including a sensor configured to selectively sense light in the red wavelength spectrum, and the sensor may include a reflective electrode and a semi-transmissive electrode facing each other, a photoelectric conversion layer between the reflective electrode and the semi-transmissive electrode and including a wavelength-selective photoelectric conversion material having a maximum absorption wavelength in a wavelength region of greater than about 600 nm and less than or equal to about 750 nm, and a buffer layer between the reflective electrode and the semi-transmissive electrode and having a thickness of greater than or equal to about 70 nm and less than or equal to about 110 nm.

Alternatively or additionally, according to some example embodiments, a sensor-embedded display panel includes unit pixels repeatedly arranged, the unit pixels including at least one red subpixel configured to display red and including a red light emitting element, at least one green subpixel configured to display green and including a green light emitting element, at least one blue subpixel configured to display blue and including a blue light emitting element, and a sensor pixel including a sensor configured to selectively sense light in the green wavelength spectrum, and the sensor includes a reflective electrode and a semi-transmissive electrode facing each other, a photoelectric conversion layer between the reflective electrode and the semi-transmissive electrode and including a wavelength-selective photoelectric conversion material having a maximum absorption wavelength in a wavelength region of greater than or equal to about 500 nm and less than or equal to about 600 nm, and a buffer layer between the reflective electrode and the semi-transmissive electrode and having a thickness of greater than or equal to about 20 nm and less than or equal to about 50 nm.

A sensor capable of improving performance by being integrated with a display panel is provided.

### BRIEF DESCRIPTION OF THE DRAWINGS

FIG. 1 is a plan view illustrating an example of a sensor-embedded display panel according to some example embodiments,

FIG. 2 is a cross-sectional view illustrating an example of a sensor-embedded display panel according to some example embodiments,

FIG. 3 is a graph showing optical characteristics of a wavelength-selective photoelectric conversion material according to an example embodiment,

FIG. 4 is a graph showing absorbance according to the thickness of a buffer layer when a wavelength-selective photoelectric conversion material having the optical characteristics of FIG. 3 is included in a photoelectric conversion layer of a sensor according to an example embodiment,

FIG. 5 is a graph showing optical characteristics of a wavelength-selective photoelectric conversion material according to another example embodiment,

FIG. 6 is a graph showing absorbance according to the thickness of a buffer layer when a wavelength-selective photoelectric conversion material having optical characteristics of FIG. 5 is included in a photoelectric conversion layer of a sensor according to an example embodiment,

FIG. 7 is a schematic view illustrating an example of a smart phone as an electronic device according to an example embodiment, and

FIG. 8 is a schematic view illustrating an example of a configuration diagram of an electronic device according to some example embodiments.

### DETAILED DESCRIPTION

Hereinafter, various example embodiments will be described in detail so that a person of ordinary skill in the art would understand the same. However, a structure that is actually applied may be implemented in various different forms and is not limited to the example embodiments described herein.

In the drawings, the thickness of layers, films, panels, regions, etc., are exaggerated for clarity. It will be understood that when an element such as a layer, film, region, or substrate is referred to as being “on” another element, it may be directly on the other element or intervening elements may also be present. In contrast, when an element is referred to as being “directly on” another element, there are no intervening elements present.

In the drawings, parts having no relationship with the description are omitted for clarity of variously described embodiments, and the same or similar constituent elements are indicated by the same reference numeral throughout the specification.

Hereinafter, the terms “lower” and “upper” are used for better understanding and ease of description, but do not limit the location relationship.

Hereinafter, when a definition is not otherwise provided, the energy level is or corresponds to the highest occupied molecular orbital (HOMO) energy level or corresponds to the lowest unoccupied molecular orbital (LUMO) energy level.

Hereinafter, when a definition is not otherwise provided, a work function or an energy level is expressed as an absolute value from a vacuum level. In addition, when the work function or the energy level is referred to be deep, high, or large, it may have a large absolute value based on “0 eV” of the vacuum level while when the work function or the energy level is referred to be shallow, low, or small, it may have a small absolute value based on “0 eV” of the vacuum level. Further, the differences between the work function and/or the energy level may be values obtained by subtracting a small value of the absolute value from a large value of the absolute value.

Hereinafter, when a definition is not otherwise provided, the HOMO energy level may be evaluated with an amount of photoelectrons emitted by energy when irradiating UV light to a thin film using AC-2 (Hitachi) and/or AC-3 (Riken Keiki Co., Ltd.).

Hereinafter, when a definition is not otherwise provided, the LUMO energy level may be obtained by obtaining an energy bandgap using a UV-Vis spectrometer (Shimadzu Corporation), and then calculating the LUMO energy level from the energy bandgap and the already measured HOMO energy level.

Hereinafter, a sensor-embedded display panel according to some example embodiments is described.

The sensor-embedded display panel according to some example embodiments may perform both a display function and a recognition function (e.g., biometric recognition function), and may be an in-cell type display panel in which a sensor performing a recognition function (e.g., biometric recognition function) is embedded in the display panel.

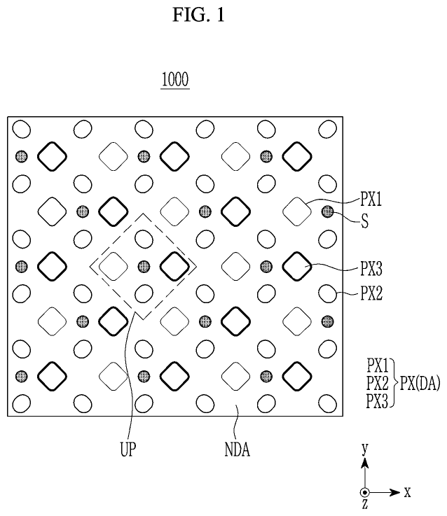

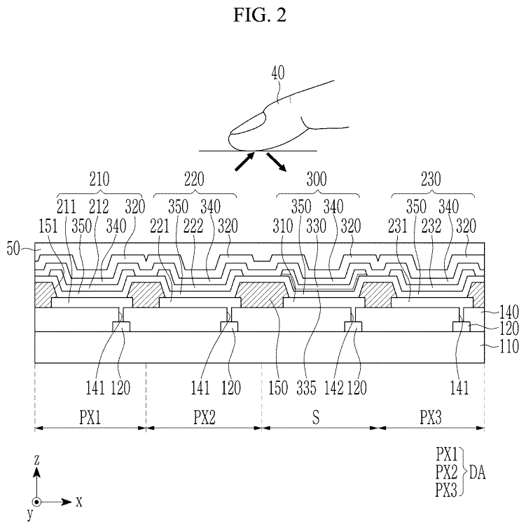

FIG. 1 is a plan view illustrating an example of a sensor-embedded display panel according to some example embodiments, and FIG. 2 is a cross-sectional view illustrating an example of a sensor-embedded display panel according to some example embodiments.

Referring to FIGS. 1 and 2, a sensor-embedded display panel 1000 according to some example embodiments includes a plurality of subpixels PX1, PX2, and PX3 that are configured to display different colors from each other. The sensor-embedded display panel 1000 further includes a plurality of sensor pixels S.

The plurality of subpixels PX1, PX2, and PX3 may be configured to display at least three primary colors, for example, a first subpixel PX1, a second subpixel PX2, and a third subpixel PX3 configured to display different first color, second color, and third color selected from red, green, and blue. For example, the first color, the second color, and the third color may be red, green, and blue, respectively; however, example embodiments are not limited thereto. The first subpixel PX1 may be a red subpixel configured to display red, the second subpixel PX2 may be a green subpixel configured to display green, and the third subpixel PX3 may be a blue subpixel configured to display blue. However, example embodiments are not limited thereto, and in some example embodiments an auxiliary subpixel (not shown) such as a white subpixel may be further included. An area occupied by the plurality of subpixels PX1, PX2, and PX3 and displaying colors by the plurality of subpixels PX may be or may correspond to a display area DA configured to display an image. Furthermore, the specifical layout and/or shape and/or size of the plurality of subpixels PX1, PX2, and PX3 are not limited to those as shown in the figures. For example, a shape of one or more of the subpixels PX1, PX2, and PX3 may be rectangular, e.g., square, and/or curved, e.g., elliptical; example embodiments are not limited thereto. Additionally, an orientation of the plurality of subpixels PX1, PX2, and PX3 is not limited to that as shown in FIG. 1.

The sensor pixel S may be or may include a sensor 300 (refer to FIG. 2) such as an optical type recognition sensor (e.g., a biometric sensor). The sensor pixel S may be in a non-display area NDA that is an area other than the display area DA, and in some example embodiments may be arranged between at least two selected from the first subpixel PX1, the second subpixel PX2, and the third subpixel PX3. All sensor pixels S included in the sensor-embedded display panel 1000 may be configured to selectively sense light of a single wavelength spectrum, and may be configured to, for example, selectively sense light of a green wavelength spectrum or selectively sense light of a red wavelength spectrum.

At least one first subpixel PX1, at least one second subpixel PX2, at least one third subpixel PX3, and at least one sensor pixel S may form one or may correspond to unit pixel UP and may be repeatedly arranged in rows and/or columns, e.g., in a matrix form, on most of or the whole surface of the sensor-embedded display panel 1000. FIG. 1 illustrates a structure including one first subpixel PX1, two second subpixels PX2, one third subpixel PX3, and one sensor pixel S in a unit pixel UP as an example, but the present disclosure is not limited thereto. Although an example arrangement is shown in the drawing, the arrangement of the subpixels PX and the sensor pixels S may vary without being limited thereto. There may be inactive and/or dummy unit pixels (not illustrated), for example at the edge of the display area DA.

Referring to FIG. 2, each of the first subpixel PX1, the second subpixel PX2, and the third subpixel PX3 includes a light emitting element. For example, the first subpixel PX1 may include a first light emitting element (red light emitting element) 210 configured to emit light of a red wavelength spectrum, the second subpixel PX2 may include a second light emitting element (green light emitting element) 220 configured to emit light of a green wavelength spectrum, and the third subpixel PX3 may include a third light emitting element (blue light emitting element) 230 configured to emit light of a blue wavelength spectrum. However, example embodiments are not limited thereto, and at least one of the first subpixel PX1, the second subpixel PX2, or the third subpixel PX3 may include a light emitting element configured to emit light of a combination of a red wavelength spectrum, a green wavelength spectrum, and a blue wavelength spectrum, for example, a white wavelength spectrum, and may be configured to display a first color (e.g., red), a second color (e.g., green) or a third color (e.g., blue) through a color filter (not shown).

The sensor pixel S includes a sensor 300. The sensor 300 may be or may include an optical type recognition sensor (e.g., a biometric sensor), and may be configured to absorb light generated by reflection of light emitted from at least one of the first, second or third light emitting elements 210, 220, and 230 in the display area DA, by a recognition target 40 such as but not limited to one or more of a living body, a tool, or an object to convert the absorbed light into an electrical signal. Herein, the living body may be or may include one or more of a finger, a fingerprint, a palm, an iris, a face, and/or a wrist, but is not limited thereto. The sensor 300 may be or may include or be included in, for example, one or more of a fingerprint sensor, an illumination sensor, an iris sensor, a distance sensor, a blood vessel distribution sensor, and/or a heart rate sensor, but is not limited thereto.

The sensor-embedded display panel 1000 includes a substrate 110; a thin film transistor 120 on the substrate 110; an insulation layer 140 on the thin film transistor 120; a pixel definition layer 150 on the insulation layer 140; and first, second, or third light emitting elements 210, 220, and 230 and the sensor 300 in a space partitioned by the pixel definition layer 150.

The substrate 110 may be or may include a light-transmitting substrate, for example, a glass substrate or a polymer substrate. The polymer substrate may include, for example, polycarbonate, polymethylmethacrylate, polyethyleneterephthalate, polyethylenenaphthalate, polyimide, polyamide, polyamideimide, polyethersulfone, polyorganosiloxane, styrene-ethylene-butylene-styrene copolymer, polyurethane, polyacrylate, polyolefin, or any combination thereof, but is not limited thereto.

A plurality of thin film transistors 120 are formed on the substrate 110. One or more thin film transistor 120 may be included in each subpixel PX and sensor pixel S, and may include, for example, at least one switching thin film transistor and/or at least one driving thin film transistor. The substrate 110 upon which the thin film transistor 120 is formed may be referred to as a thin film transistor substrate (TFT substrate) or a thin film transistor backplane (TFT backplane).

The insulation layer 140 may cover the substrate 110 and the thin film transistor 120 and may be formed on the whole surface of the substrate 110. The insulation layer 140 may be or may include a planarization layer and/or a passivation layer, and may include an organic insulating material, an inorganic insulating material, an organic-inorganic insulating material, or any combination thereof. The insulation layer 140 may have or may define a plurality of contact holes 141 for electrically connecting the first, second, and third light emitting elements 210, 220, and 230 and the thin film transistor 120 and a plurality of contact holes 142 for electrically connecting the sensor 300 and the thin film transistor 120.

The pixel definition layer 150 may also be formed on the whole surface of the substrate 110 and may be between adjacent subpixels PXs and between the subpixel PX and the sensor pixel S to partition each subpixel PX and sensor pixel S. The pixel definition layer 150 may have or may define a plurality of openings 151 positioned in each subpixel PX and in each sensor pixel S, and any one of first, second, or third light emitting elements 210, 220, and 230 and the sensor 300 may be in each opening 151.

The first, second and third light emitting elements 210, 220, and 230 and the sensor 300 are formed on or at least partly in and on the substrate 110 (or thin film transistor substrate), and are repeatedly arranged along an in-plane direction (e.g., xy direction) of the substrate 110. As described above, the first, second, and third light emitting elements 210, 220, and 230 may be included in the first subpixel PX1, the second subpixel PX2, and the third subpixel PX3, respectively, and the sensor 300 may be included in the sensor pixel S. The first, second, and third light emitting elements 210, 220, and 230 and the sensor 300 may be electrically connected to separate thin film transistors 120 and may be driven independently.

The first, second, and third light emitting elements 210, 220, and 230 may be configured to emit light of different wavelength spectra belonging to the visible light wavelength spectrum, and may be configured to independently emit one light of a red wavelength spectrum, a green wavelength spectrum, a blue wavelength spectrum, or any combination thereof. For example, the first light emitting element 210 may be or may include a red light emitting element configured to selectively emit light of a red wavelength spectrum, the second light emitting element 220 may be or may include a green light emitting element configured to selectively emit light of a green wavelength spectrum, and the third light emitting element 230 may be or may include a blue light emitting element configured to selectively emit light in a blue wavelength spectrum. Herein, the red wavelength spectrum, the green wavelength spectrum, and the blue wavelength spectrum may have a maximum emission wavelength (λ_{max,L}) in a wavelength region of greater than about 600 nm and less than about 750 nm, about 500 nm to about 600 nm, and greater than or equal to about 380 nm and less than about 500 nm, respectively.

The first, second, and third light emitting elements 210, 220, and 230 may be or may include, for example, light emitting diodes, for example organic light emitting diodes (OLEDs) including an organic light emitting material.

The sensor 300 may be configured to absorb light belonging to a wavelength spectrum of light emitted from any one of the first, second, or third light emitting elements 210, 220, and 230 and convert the absorbed light into an electrical signal, and for example, the sensor 300 may be a single photosensor configured to sense light of any one of a red wavelength spectrum, the green wavelength spectrum, or the blue wavelength spectrum. For example, the sensor 300 may be configured to selectively sense light of any one of a green wavelength spectrum or a red wavelength spectrum.

The sensor 300 may be, for example, a photoelectric conversion diode, for example an organic photoelectric conversion diode including an organic photoelectric conversion material.

Each of the first, second, and third light emitting elements 210, 220, and 230 and the sensor 300 may include pixel electrodes 211, 221, 231, and 310; a common electrode 320 facing the pixel electrodes 211, 221, 231, and 310; light emitting layers 212, 222, and 232 or a photoelectric conversion layer 330 between the pixel electrodes 211, 221, 231, and 310 and the common electrode 320; a first common auxiliary layer 340; and a second common auxiliary layer 350. The sensor 300 further include a buffer layer 335.

The first, second, and third light emitting elements 210, 220, and 230, which are light emitting diodes, and the sensor 300, which is a photoelectric conversion diode, may share some constituent elements, and may share the common electrode 320, the first common auxiliary layer 340, and the second common auxiliary layer 350 formed on the whole surface of the substrate 110.

The common electrode 320 is continuously formed on the light emitting layers 212, 222, and 232 and the photoelectric conversion layer 330, and the first, second, and third light emitting elements 210, 220, and 230 and the sensor 300 may be applied with a common voltage.

The common electrode 320 may be or may include a light transmitting electrode configured to transmit light, and may further be or include an incident electrode and/or a light-receiving electrode at a side where light is incident and through which light passes. The common electrode 320 may be or may include a semi-transmissive electrode configured to transmit a portion of the light and reflect a portion of the light, and the semi-transmissive electrode may have, for example, light transmittance of about 20% to about 70%, about 30% to about 70%, about 20% to about 60%, about 30% to about 60%, about 20% to about 50% or about 30% to about 50% and reflectance of about 30% to about 80%, about 30% to about 70%, about 30% to about 60%, about 40% to about 80%, about 40% to about 70%, or about 40% to about 60%. Herein, the light transmittance and reflectance may be average light transmittance and average reflectance in the visible light wavelength spectrum (e.g., greater than or equal to about 380 nm and less than about 750 nm).

The semi-transmissive electrode may include a very thin metal layer, e.g., from a few nanometers to several tens of nanometers. The metal layer may have, for example, a thickness of about 2 nm to about 50 nm, about 2 nm to about 40 nm, about 2 nm to about 30 nm, about 2 nm to about 25 nm, about 2 nm to about 20 nm, about 2 nm to about 15 nm, about 5 nm to about 50 nm, about 5 nm to about 40 nm, about 5 nm to about 30 nm, about 5 nm to about 25 nm, about 5 nm to about 20 nm, or about 5 nm to about 15 nm, and within the above thickness range, effective semi-transmission properties of the aforementioned light transmittance and reflectance may be exhibited. The semi-transmissive electrode for example, may be formed to a very thin thickness as described above with aluminum (Al), magnesium (Mg), silver (Ag), gold (Au), or any combination thereof (e.g., an alloy thereof, for example, magnesium-silver (Mg—Ag) or magnesium-aluminum (Mg—Al)), but is not limited thereto. The semi-transmissive electrode may be formed of a semi-transmissive layer or may have a semi-transmissive layer/light transmitting layer or a light transmitting layer/semi-transmissive layer/light transmitting layer, and the semi-transmissive layer may have one layer or two or more layers.

The first common auxiliary layer 340 may be under the common electrode 320 and may be continuously formed by being connected to each other between the light emitting layers 212, 222, and 232 and the photoelectric conversion layer 330 and the common electrode 320.

The first common auxiliary layer 340 may be a charge auxiliary layer (e.g., an electron auxiliary layer) that facilitates injection and/or transfer of electric charges (e.g., electrons) from the common electrode 320 to the light emitting layers 212, 222, and 232. The first common auxiliary layer 340 may include a charge transport material, for example, an electron transport material. For example, a LUMO energy level of the first common auxiliary layer 340 (e.g. electron transport material) may be between LUMO energy levels of the light emitting layers 212, 222, and 232 (the organic light emitting material of the light emitting layer) and a work function of the common electrode 320. The work function of the common electrode 320, the LUMO energy levels of the first common auxiliary layer 340, and the LUMO energy levels of the light emitting layers 212, 222, and 232 may sequentially become shallow. For example, the LUMO energy level of the first common auxiliary layer 340 (e.g., electron transport material) may be about 2.9 eV to about 3.3 eV, and within the above range, about 3.0 to about 3.2 eV, but is not limited thereto.

The first common auxiliary layer 340 may include an organic material, an inorganic material, an organic-inorganic material, or any combination thereof satisfying the LUMO energy level, for example a halogenated metal such as LiF, NaCl, CsF, RbCl, and RbI; a lanthanides metal such as Yb; a metal oxide such as Li₂O or BaO; Liq (lithium 8-hydroxy quinolate), Alq3 (tris(8-hydroxyquinolinato)aluminum), 1,3,5-tri[(3-pyridyl)-phen-3-yl]benzene, 2,4,6-tris (3′-(pyridin-3-yl)biphenyl-3-yl)-1,3,5-triazine, 2-(4-(N-phenylbenzoimidazolyl-1-ylphenyl)-9,10-dinaphthylanthracene, TPBi (1,3,5-tri(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tertbutylphenyl-1,2,4-triazole), NTAZ (4-(naphthalen-1-yl)-3,5-diphenyl-4H-1,2,4-triazole), tBu-PBD (2-(4-biphenylyl)-5-(4-tert-butylphenyl)-1,3,4-oxadiazole), (bis(2-methyl-8-hydroxyquinolinolato-N1,O8)-(1,1′-biphenyl-4-olato)aluminum), Bebq2 (berylliumbis(benzoquinolin-10-olate), ADN (9,10-di(naphthalene-2-yl)anthracene), BmPyPhB (1,3-bis[3,5-di(pyridin-3-yl)phenyl]benzene), or any combination thereof, but is not limited thereto. The first common auxiliary layer 340 may be one layer or two or more layers.

The second common auxiliary layer 350 may face the first common auxiliary layer 340 with the light emitting layers 212, 222, and 232 and the photoelectric conversion layer 330 interposed therebetween. The light emitting layers 212, 222, and 232 may be continuously formed under the photoelectric conversion layer 330 and on the pixel electrodes 211, 221, 231, and 310.

The second common auxiliary layer 350 may be or may include a charge auxiliary layer (e.g., hole auxiliary layer) that facilitates injection and/or transfer of electric charges (e.g., holes) from the pixel electrodes 211, 221, and 231 to the light emitting layers 212, 222, and 232. For example, the HOMO energy level of the second common auxiliary layer 350 may be between the HOMO energy level of the light emitting layers 212, 222, and 232 and the work function of the pixel electrodes 211, 221, and 231. The work function of the pixel electrodes 211, 221, and 231, the HOMO energy level of the second common auxiliary layer 350, and the HOMO energy level of the light emitting layers 212, 222, and 232 may become sequentially deep.

The second common auxiliary layer 350 may include an organic material, an inorganic material, an organic-inorganic material, or any combination thereof satisfying the HOMO energy level, for example a phthalocyanine compound such as copper phthalocyanine; DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino] triphenylamine), TDATA (4,4′4″-tris(N,N-diphenylamino)triphenylamine), 2-TNATA (4,4′,4″-tris{N-(2-naphthyl)-N-phenylamino}-triphenylamine), PEDOT/PSS (poly(3,4-ethylenedioxythiophene)/poly(4-styrenesulfonate)), PANI/DBSA (polyaniline/dodecylbenzenesulfonic acid), PANI/CSA (polyaniline/Camphor sulfonic acid), PANI/PSS (polyaniline/poly(4-styrenesulfonate)), NPB (N,N′-di(naphthalene-I-yl)-N,N′-diphenylbenzidine), polyetherketone including triphenylamine (TPAPEK), 4-isopropyl-4′-methyldiphenyliodonium[tetrakis(pentafluorophenyl)borate], HAT-CN (dipyrazino[2,3-f: 2′,3′-h] quinoxaline-2,3,6,7,10,11-hexacarbonitrile), a carbazole-based derivative such as N-phenylcarbazole, polyvinylcarbazole, and the like, a fluorene-based derivative, TPD (N,N′-bis(3-methylphenyl)-N,N′-diphenyl-[1,1-biphenyl]-4,4′-diamine), a triphenylamine-based derivative such as TCTA (4,4′,4″-tris(N-carbazolyl)triphenylamine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), mCP (1,3-bis(N-carbazolyl)benzene), or any combination thereof, but is not limited thereto. The second common auxiliary layer 350 may be one layer or two or more layers.

Each of the first, second and third light emitting elements 210, 220, and 230 and the sensor 300 includes pixel electrodes 211, 221, 231, and 310 facing the common electrode 320. The pixel electrodes 211, 221, 231, and 310 may be separated from each other for each subpixel PX and sensor pixel S, and may be electrically connected to separate thin film transistors 120 to be independently driven. One of the pixel electrodes 211, 221, 231, and 310 or the common electrode 320 is or corresponds to an anode and the other is or corresponds to a cathode. For example, the pixel electrodes 211, 221, 231, and 310 may be or may correspond to an anode, and the common electrode 320 may be or may correspond to a cathode.

The pixel electrodes 211, 221, 231, and 310 may be or may include reflective electrodes. The reflective electrode may ideally include a reflective layer configured to reflect all light, and the reflective layer may have, for example, a light transmittance of 0 to about 5% and/or a reflectance of about 80% to about 100%. Herein, the light transmittance and reflectance may be average light transmittance and average reflectance in the visible light wavelength spectrum (e.g., greater than or equal to about 380 nm and less than about 750 nm).

The reflective layer may include an optically opaque material, for example a metal, a metal nitride, or any combination thereof, for example silver (Ag), copper (Cu), aluminum (Al), gold (Au), titanium (Ti), chromium (Cr), nickel (Ni), an alloy thereof, a nitride thereof (e.g., TiN), or any combination thereof, but is not limited thereto.

The reflective electrode may be formed of a reflective layer or may have a stacked structure of a reflective layer/transmissive layer or a transmissive layer/reflective layer/transmissive layer, and the reflective layer may be one layer or two or more layers. The light transmitting layer may have a light transmittance of greater than or equal to about 85%, and may include, for example, an oxide conductor such as one or more of indium tin oxide (ITO), indium zinc oxide (IZO), zinc tin oxide (ZTO), aluminum tin oxide (ATO), and aluminum zinc oxide (AZO), but is not limited thereto.

Each of the first, second, and third light emitting elements 210, 220, and 230 includes light emitting layers 212, 222, and 232 between the pixel electrodes 211, 221, and 231 and the common electrode 320. Each of the light emitting layer 212 included in the first light emitting element 210, the light emitting layer 222 included in the second light emitting element 220, and the light emitting layer 232 included in the third light emitting element 230 may be configured to emit light in the same or different wavelength spectra and may be configured to emit light in, for example a red wavelength spectrum, a green wavelength spectrum, a blue wavelength spectrum, or any combination thereof.

For example, when the first light emitting element 210, the second light emitting element 220, and the third light emitting element 230 are a red light emitting element, a green light emitting element, and a blue light emitting element, respectively, the light emitting layer 212 included in the first light emitting element 210 may be a red light emitting layer configured to emit light in a red wavelength spectrum, the light emitting layer 222 included in the second light emitting element 220 may be a green light emitting layer configured to emit light in a green wavelength spectrum, and the light emitting layer 232 included in the third light emitting element 230 may be a blue light emitting layer configured to emit light in a blue wavelength spectrum. Herein, the red wavelength spectrum, the green wavelength spectrum, and the blue wavelength spectrum may have a maximum absorption wavelength (λ_{max,A}) of greater than about 600 nm and less than about 750 nm, about 500 nm to about 600 nm, and greater than or equal to about 380 nm and less than about 500 nm.

For example, when at least one of the first light emitting element 210, the second light emitting element 220, or the third light emitting element 230 is or corresponds to a white light emitting element, the light emitting layer of the white light emitting element may be configured to emit light of a full visible light wavelength spectrum, for example, light in a wavelength spectrum of greater than or equal to about 380 nm and less than about 750 nm, about 400 nm to about 700 nm, or about 420 nm to about 700 nm.

The light emitting layers 212, 222, and 232 may include at least one host material and a fluorescent or phosphorescent dopant, and at least one of the at least one host material or the fluorescent or phosphorescent dopant may be an organic light emitting material. The organic light emitting material may include, for example, a low-molecular organic light emitting material, and may include, for example, a deposit-able organic light emitting material (or an organic light emitting material that may be deposited, e.g., in a chemical vapor deposition process).

The organic light emitting material included in the light emitting layers 212, 222, and 232 is not particularly limited as long as it is an electroluminescent material capable of emitting light of a particular (e.g., a predetermined) wavelength spectrum, and examples thereof may include perylene; rubrene; 4-(dicyanomethylene)-2-methyl-6-[p-(dimethylamino)styryl]-4H-pyran; coumarin or a derivative thereof; carbazole or a derivative thereof; TPBi (2,2′,2″-(1,3,5-benzinetriyl)-tris(1-phenyl-1-H-benzimidazole); TBADN (2-t-butyl-9,10-di(naphth-2-yl)anthracene); AND (9,10-di(naphthalene-2-yl)anthracene); CBP (4,4′-bis(N-carbazolyl)-1,1′-biphenyl); TCTA (4,4′,4″-tris(carbazol-9-yl)-triphenylamine); TPBi (1,3,5-tris(N-phenylbenzimidazole-2-yl)benzene); TBADN (3-tert-butyl-9,10-di(naphth-2-yl)anthracene); DSA (distyrylarylene); CDBP(4,4′-bis(9-carbazolyl)-2,2′-dimethyl-biphenyl); MADN (2-Methyl-9,10-bis(naphthalen-2-yl)anthracene); TCP (1,3,5-tris(carbazol-9-yl)benzene); Alq3 (tris(8-hydroxyquinolino)lithium); an organometallic compound including Pt, Os, Ti, Zr, Hf, Eu, Tb, Tm, Rh, Ru, Re, Be, Mg, Al, Ca, Mn, Co, Cu, Zn, Ga, Ge, Pd, Ag and/or Au, a derivative thereof, or any combination thereof, but are not limited thereto.

The sensor 300 includes a photoelectric conversion layer 330 and a buffer layer 335 between the first common auxiliary layer 340 and the second common auxiliary layer 350. The buffer layer 335 may be under the photoelectric conversion layer 330 and may be between the second common auxiliary layer 350 and the photoelectric conversion layer 330. However, the buffer layer 335 is not limited thereto and may be between the first common auxiliary layer 340 and the photoelectric conversion layer 330.

The photoelectric conversion layer 330 and the buffer layer 335 may be arranged in parallel with the light emitting layers 212, 222, and 232 of the first, second, and third light emitting elements 210, 220, and 230 along the in-plane direction (e.g., xy direction) of the substrate 110.

The photoelectric conversion layer 330 may be configured to absorb light of a specific (e.g., a dynamically determined, or alternatively a predetermined) wavelength spectrum and convert the absorbed light into an electrical signal, and may be configured to absorb light generated by reflection of the aforementioned light emitted from one of the first, second, or third light emitting elements 210, 220, and 230 by the recognition target 40 and convert it into an electrical signal. The photoelectric conversion layer 330 may be configured to absorb light of, for example, a green wavelength spectrum or a red wavelength spectrum and may include a wavelength-selective photoelectric conversion material configured to selectively absorb light of a green wavelength spectrum or a red wavelength spectrum and converting it into an electrical signal.

For example, the photoelectric conversion layer 330 may include a wavelength-selective photoelectric conversion material (green photoelectric conversion material) having a maximum absorption wavelength (λ_{max,A}) in a wavelength range of about 500 nm to about 600 nm.

The wavelength-selective photoelectric conversion material (e.g., the green photoelectric conversion material) may have wavelength selectivity in the green wavelength region of the visible light wavelength region, and the absorption amount in the green wavelength spectrum may be significantly higher than the absorption amount in the rest of the wavelength spectrum in the visible light wavelength region. For example, the absorption amount in the wavelength spectrum of about 500 nm to about 600 nm of the wavelength-selective photoelectric conversion material (e.g., the green photoelectric conversion material) may be about 70% to about 100%, and within the above range, about 75% to about 100%, about 80% to about 100%, about 85% to about 100%, or about 90% to about 100% of the total absorption amount in the visible light wavelength spectrum. The maximum absorption wavelength (λ_{max,A}) of the wavelength-selective photoelectric conversion material (green photoelectric conversion material) may fall within the range of about 510 nm to 580 nm, about 520 nm to about 570 nm, about 520 nm to about 560 nm, about 520 nm to about 550 nm, or about 520 nm to about 540 nm within the above range.

The wavelength-selective photoelectric conversion material (green photoelectric conversion material) may have a maximum extinction coefficient (k) in a wavelength range of about 500 nm to about 600 nm, and the extinction coefficient (k) at the maximum absorption wavelength (λ_{max,A}) may be, for example, greater than or equal to about 0.5, greater than or equal to about 0.7, or greater than or equal to about 0.8, and within this range, for example, about 0.5 to about 1.5, about 0.7 to about 1.5, or about 0.8 to about 1.5.

A refractive index (n) at the maximum absorption wavelength (λ_{max,A}) of the wavelength-selective photoelectric conversion material (green photoelectric conversion material) may be about 2.0 to about 3.0, and within the above range about 2.1 to about 2.8 or about 2.2 to about 2.6.

For example, the photoelectric conversion layer 330 may include a wavelength-selective photoelectric conversion material (e.g., a red photoelectric conversion material) having a maximum absorption wavelength (λ_{max,A}) in a wavelength region of greater than about 600 nm and less than about 750 nm. The wavelength-selective photoelectric conversion material (red photoelectric conversion material) may have wavelength selectivity in the red wavelength region of the visible light wavelength region, and the absorption amount in the red wavelength spectrum may be significantly higher than the absorption amount in the rest of the wavelength spectrum in the visible light wavelength region. For example, the absorption amount in the wavelength spectrum of greater than about 600 nm and less than about 750 nm of the wavelength-selective photoelectric conversion material (e.g., the red photoelectric conversion material) may be about 70% to about 100%, and within the above range, about 75% to about 100%, about 80% to about 100%, about 85% to about 100%, or about 90% to about 100% of the total absorption amount in the visible light wavelength spectrum. The maximum absorption wavelength (Amax, A) of the wavelength-selective photoelectric conversion material (e.g., the red photoelectric conversion material) may fall within the range of about 610 nm to about 730 nm, about 615 nm to about 700 nm, about 620 nm to about 680 nm, or about 620 nm to about 660 nm.

The wavelength-selective photoelectric conversion material (red photoelectric conversion material) may have a maximum extinction coefficient (k) in a wavelength range of greater than about 600 nm and less than about 750 nm, and the extinction coefficient (k) at the maximum absorption wavelength (λ_{max,A}) may be, for example, greater than or equal to about 0.5, greater than or equal to about 0.7, or greater than or equal to about 0.8, and within this range, for example, about 0.5 to about 1.8, about 0.7 to about 1.8, or about 0.8 to about 1.8.

A refractive index (n) at the maximum absorption wavelength (λ_{max,A}) of the wavelength-selective photoelectric conversion material (red photoelectric conversion material) may be about 2.0 to about 3.0, and within the above range about 2.1 to about 2.8 or about 2.2 to about 2.6.

The photoelectric conversion layer 330 may further include a counter material capable of forming a pn junction with the wavelength-selective photoelectric conversion material. The counter material may be or may include a light absorbing material or a non-light absorbing material, such as a transparent material that does not substantially absorb light in the visible light wavelength spectrum. The transparent material may have a wide energy bandgap so as not to substantially absorb light in the visible light wavelength spectrum, for example, an energy bandgap of greater than or equal to about 2.5 eV, and within the above range, for example, about 2.5 eV to about 6.0 eV. One of the wavelength-selective photoelectric conversion material or the counter material is a p-type semiconductor and the other is an n-type semiconductor. For example, the wavelength-selective photoelectric conversion material may be a p-type semiconductor and the counter material may be an n-type semiconductor.

The photoelectric conversion layer 330 is or includes a mixed monolayer in which a wavelength-selective photoelectric conversion material and a counter material are mixed; a bi-layer including a first photoelectric conversion layer including a wavelength-selective photoelectric conversion material and a second photoelectric conversion layer including a counter material; or a triple layer including a first photoelectric conversion layer including a wavelength-selective photoelectric conversion material, a mixed monolayer in which the wavelength-selective photoelectric conversion material and a counter material are mixed, and a second photoelectric conversion layer including a counter material, but is not limited thereto.

The buffer layer 335 is adjacent to the photoelectric conversion layer 330 and between the photoelectric conversion layer 330 and the second common auxiliary layer 350.

The buffer layer 335 may include a charge transport material, and may include, for example, a charge transport material (such as a hole transport material) that is the same as or different from the charge transport material (e.g., the hole transport material) included in the second common auxiliary layer 350. The charge transport material (e.g., the hole transport material) is as described above.

The buffer layer 335 is adjacent to the photoelectric conversion layer 330 and between the first common auxiliary layer 340 and the second common auxiliary layer 350 to effectively control an optical path length of the microcavity described later and thereby to improve the wavelength selectivity of the sensor 300.

A thickness of the buffer layer 335 is related to the absorption spectrum of the photoelectric conversion layer 330, and specifically, by considering the extinction coefficient (k) and the refractive index (n) at the maximum absorption wavelength (λ_{max,A}) of the wavelength-selective photoelectric conversion material included in the photoelectric conversion layer 330, a combination of the photoelectric conversion layer 330 and the buffer layer 335 may have a thickness that exhibits maximum absorption.

For example, when the photoelectric conversion layer 330 includes a wavelength-selective photoelectric conversion material (green photoelectric conversion material) having a maximum absorption wavelength (λ_{max,A}) in a wavelength range of about 500 nm to about 600 nm, a thickness of the buffer layer 335 may be between about 20 nm and about 50 nm. Within the above range, the thickness of the buffer layer 335 may be about 20 nm to about 40 nm or about 25 nm to about 35 nm.

When the buffer layer 335 has the above thickness, a sum of the thicknesses of the photoelectric conversion layer 330 and the buffer layer 335 may be, for example, about 50 nm to about 100 nm, within the above range about 55 nm to about 95 nm, about 60 nm to about 90 nm, about 65 nm to about 85 nm, or about 70 nm to about 80 nm.

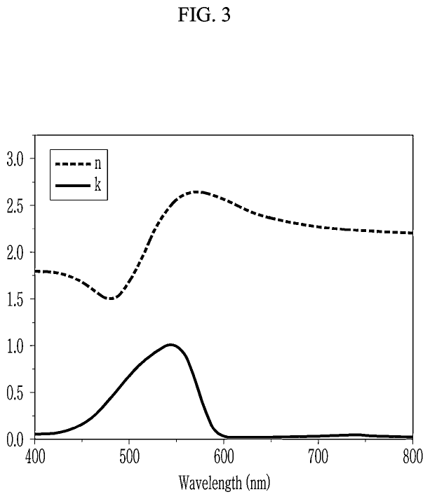

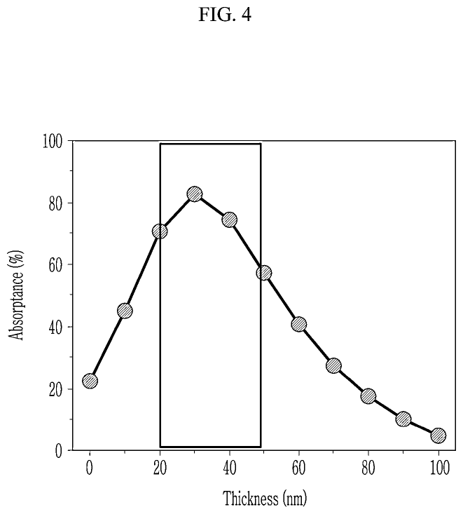

FIG. 3 is a graph showing optical characteristics of a wavelength-selective photoelectric conversion material according to some example embodiments, and FIG. 4 is a graph showing absorbance according to the thickness of a buffer layer when a wavelength-selective photoelectric conversion n material having the optical characteristics of FIG. 3 is included in a photoelectric conversion layer of a sensor according to various example embodiments.

An amount of light absorbed in FIG. 4 is related to an internal optical E-field, the internal optical E-field of each layer of the sensor 300 is calculated using a transfer matrix method (TMM) from the refractive index n, extinction coefficient k, and thickness t of each layer, and the amount of light absorbed by each layer inside the sensor 300 using the internal optical E-field of each layer is calculated using the calculation formula disclosed in Journal of Applied Physics 86, 487 (1999), the entire contents of which are included herein by reference, and the corresponding MATLAB program.

Referring to FIGS. 3 and 4, when the photoelectric conversion layer 330 includes a wavelength-selective photoelectric conversion material (green photoelectric conversion material) having an extinction coefficient (k) of about 0.94 and a refractive index (n) of about 2.29 at the maximum absorption wavelength (λ_{max,A}) (about 530 nm), the maximum absorbance is exhibited in the buffer layer 335 with a thickness of about 30 nm and the absorbance of greater than or equal to about 70% is exhibited in the buffer layer 335 with a thickness of about 20 nm to 50 nm.

For example, when the photoelectric conversion layer 330 includes a wavelength-selective photoelectric conversion material (e.g., the red photoelectric conversion material) having a maximum absorption wavelength in a wavelength region of greater than about 600 nm and less than about 750 nm, the thickness of the buffer layer 335 may be about 70 nm to about 110 nm. Within the above range, the thickness of the buffer layer 335 may be about 75 nm to about 110 nm, about 80 nm to about 100 nm, or about 85 nm to about 95 nm.

When the buffer layer 335 has the above thickness, a sum of the thicknesses of the photoelectric conversion layer 330 and the buffer layer 335 may be, for example, about 100 nm to about 160 nm, and within the above range, about 105 nm to about 155 nm, about 110 nm to about 150 nm, about 115 nm to about 145 nm, or about 120 nm to about 140 nm.

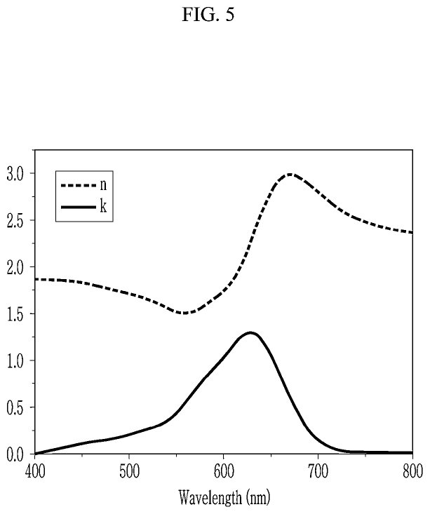

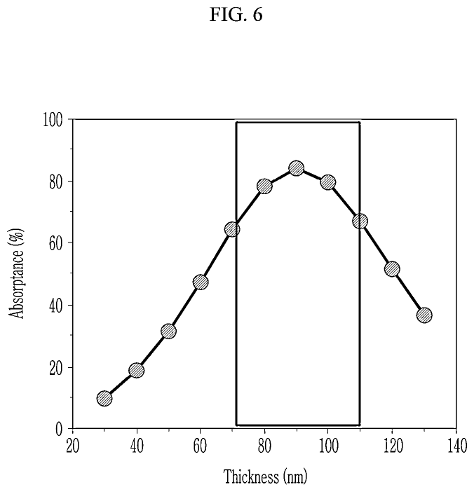

FIG. 5 is a graph showing optical characteristics of a wavelength-selective photoelectric conversion material according to another example embodiment, and FIG. 6 is a graph showing absorbance according to the thickness of a buffer layer when a wavelength-selective photoelectric conversion material having optical characteristics of FIG. 5 is included in a photoelectric conversion layer of a sensor according to an example embodiment.

Referring to FIGS. 5 and 6, the photoelectric conversion layer 330 includes a wavelength-selective photoelectric conversion material (red photoelectric conversion material) having an extinction coefficient (k) of about 1.29 and a refractive index (n) of about 2.33 at the maximum absorption wavelength (λ_{max,A}) (about 630 nm), the maximum absorbance is exhibited in the buffer layer 335 with a thickness of about 90 nm and the absorbance of greater than or equal to about 60% is exhibited in the buffer layer 335 with a thickness of about 70 nm to about 110 nm.

The sensor 300 may have a microcavity structure in which a pixel electrode 310 and a common electrode 320 face each other with a photoelectric conversion layer 330, a buffer layer 335, a first common auxiliary layer 340, and a second common auxiliary layer 350 interposed therebetween. An inner surface facing the pixel electrode 310 and the common electrode 320 may be a mirror surface configured to reflect light of a portion of the visible light wavelength spectrum. Due to this microcavity structure, light incident through the common electrode 320 may be repeatedly reflected between the pixel electrode 310 and the common electrode 320 separated by a particular (e.g., a predetermined) optical path length to cause resonance, and light of a particular (e.g., a predetermined) wavelength spectrum may be amplified by this resonance. The wavelength spectrum may include a resonance wavelength of the microcavity structure, and the resonance wavelength may be enhanced to exhibit amplified photoelectric conversion characteristics in a portion of the visible light wavelength spectrum.

The resonance wavelength may be determined according to an optical path length that is a distance between the pixel electrode 310 and the common electrode 320. The optical path length may be determined by, for example, the sum of thicknesses of the photoelectric conversion layer 330, the buffer layer 335, the first common auxiliary layer 340, and the second common auxiliary layer 350, and when the thicknesses of the photoelectric conversion layer 330, the first common auxiliary layer 340, and the second common auxiliary layer 350 are substantially constant, the optical path length may be determined by the thickness of the buffer layer 335. Therefore, by setting the thickness of the buffer layer 335 according to the optical characteristics of the aforementioned wavelength-selective photoelectric conversion material included in the photoelectric conversion layer 330, the enhanced resonance wavelength of the microcavity structure may be included in the absorption spectrum of the wavelength-selective photoelectric conversion material to exhibit amplified photoelectric conversion characteristics in a narrow wavelength range. In various example embodiments, by combining the amplified photoelectric conversion characteristics due to the thickness control of the buffer layer 335 with the original light characteristics (light absorption characteristics) of the wavelength-selective photoelectric conversion material, light of a narrower wavelength spectrum may be effectively photoelectrically converted, and thus a material limitation of the wavelength-selective photoelectric conversion material may be overcome and the photoelectric conversion efficiency of the sensor 300 may be effectively improved.

Therefore, a full width at half maximum (FWHM) of the absorption spectrum of the sensor 300 may be narrower than the FWHM of the absorption spectrum of the wavelength-selective photoelectric conversion material of the photoelectric conversion layer 330, and a FWHM of the external quantum efficiency (EQE) spectrum of the sensor 300 may be narrower than the FWHM of the EQE spectrum of the wavelength-selective photoelectric conversion material. The FWHM of the absorption spectrum may be a width of a wavelength corresponding to half of the absorption intensity at the maximum absorption wavelength (λ_{max,A}) in the absorption spectrum, and the FWHM of the EQE spectrum may be a width of a wavelength corresponding to half of an EQE value at the maximum EQE (EQEmax) in the EQE spectrum. In general, since the absorption spectrum and the EQE spectrum may have the same or extremely similar profiles, if the FWHM of the absorption spectrum is narrowed, the FWHM of the EQE spectrum may also be narrowed.

For example, the FWHM of the absorption spectrum or the FWHM of the EQE spectrum of the sensor 300 may be about 0.1 to about 0.9, about 0.1 to about 0.8, about 0.1 to about 0.7, about 0.1 to about 0.6, about 0.1 to about 0.5, about 0.2 to about 0.9, about 0.2 to about 0.8, about 0.2 to about 0.7, about 0.2 to about 0.6, about 0.2 to about 0.5, about 0.3 to about 0.9, about 0.3 to about 0.8, about 0.3 to about 0.7, about 0.3 to about 0.6, or about 0.3 to about 0.5 relative to the FWHM of the absorption spectrum or EQE spectrum of the wavelength-selective photoelectric conversion material of the photoelectric conversion layer 330.

For example, the FWHM of the absorption spectrum or the FWHM of the EQE spectrum of the sensor 300 may be less than or equal to about 100 nm, and within the above range, less than or equal to about 90 nm, less than or equal to about 80 nm, less than or equal to about 70 nm, less than or equal to about 60 nm, less than or equal to about 50 nm, less than or equal to about 45 nm, or less than or equal to about 40 nm, about 10 nm to about 100 nm, about 10 nm to about 90 nm, about 10 nm to about 80 nm, about 10 nm to about 70 nm, about 10 nm to about 60 nm, about 10 nm to about 50 nm, about 10 nm to about 45 nm, or about 10 nm to about 40 nm.

In this way, the sensor 300 may overcome or at least partially overcome or help to overcome a material limitation of the wavelength-selective photoelectric conversion material, and/or may further improve the structure by combining the absorption spectrum of the wavelength-selective photoelectric conversion material of the photoelectric conversion layer 330 and the controlled thickness of the buffer layer 335. Therefore, the sensor 300 may have an improved wavelength selectivity, and thus exhibit light absorption characteristics and photoelectric conversion characteristics in a narrower range, which may further improve the sensitivity of the sensor 300.

Referring back to FIG. 2, an encapsulation layer 50 is on the first, second, and third light emitting elements 210, 220, and 230 and the sensor 300. The encapsulation layer 50 may include, for example, a glass plate, a metal thin film, an organic layer, an inorganic layer, an organic-inorganic layer, or any combination thereof. The organic layer may include, for example, an acrylic resin, a (meth)acrylic resin, polyisoprene, a vinyl resin, an epoxy resin, a urethane resin, a cellulose resin, a perylene resin, or any combination thereof, but is not limited thereto. The inorganic layer may include, for example, oxide, nitride, and/or oxynitride, for example, silicon oxide, silicon nitride, silicon oxynitride, aluminum oxide, aluminum nitride, aluminum oxynitride, zirconium oxide, zirconium nitride, zirconium oxynitride, titanium oxide, titanium nitride, titanium oxynitride, hafnium oxide, hafnium nitride, hafnium oxynitride, tantalum oxide, tantalum nitride, tantalum oxynitride, lithium fluoride, or any combination thereof, but is not limited thereto. The organic-inorganic layer may include, for example, polyorganosiloxane, but is not limited thereto. The encapsulation layer 50 may have one layer or two or more layers.

As described above, the sensor-embedded display panel 1000 according to various example embodiments includes the first, second, and third light emitting elements 210, 220, and 230 configured to emit light in a particular (e.g., a predetermined) wavelength spectrum to display colors, and the sensor 300 configured to absorb light reflected by the recognition target 40 and convert it into an electrical signal, in the same plane on or parallel with the substrate 110, thereby performing both a display function and a recognition function (e.g., biometric recognition function). Accordingly, unlike conventional display panels in which the sensor is attached outside the display panel by manufacturing the sensor as a separate module or the sensor is formed under the display panel, the sensor-embedded display panel 1000 may improve performance without increasing the thickness, implementing a slim-type high performance sensor-embedded display panel 1000.

Alternatively or additionally, since the sensor 300 uses light emitted from the first, second, or third light emitting elements 210, 220, and 230, a recognition function (e.g., biometric recognition function) may be performed without a separate light source. Therefore, it may not be necessary to provide a separate light source outside the display panel, thereby preventing or improving a decrease in the aperture ratio of the display panel due to the area occupied by the light source, and at the same time saving power consumed by the separate light source to improve power consumption of the sensor-embedded display panel 1000.

Alternatively or additionally, since the sensor 300 may be anywhere in the non-display area NDA, the sensor 300 may be at a desired location of the sensor-embedded display panel 1000 as many as desired. Therefore, for example, by randomly or regularly arranging the sensor 300 over the entire sensor-embedded display panel 1000, the biometric recognition function may be performed on any portion of the screen of an electronic device such as a mobile device and the biometric recognition function may be selectively performed only in a specific location where the biometric recognition function is required.

Alternatively or additionally, as described above, the first, second, and third light emitting elements 210, 220, and 230 and the sensor 300 include a common electrode 320, a first common auxiliary layer 340, and a second common auxiliary layer 350. By sharing the first, second and third light emitting elements 210, 220, 230 and the sensor 300, the structure and process may be simplified compared to the case of forming the sensor 300 in a separate process.

Alternatively or additionally, the sensor 300 may be or may include an organic sensor including an organic photoelectric conversion layer, and thus may have a light absorbance twice or more than twice higher than that of an inorganic diode such as a silicon photodiode, and thus may perform a highly sensitive sensing function with a thinner thickness.

Alternatively or additionally, the sensor 300 may overcome or help improve material limitation upon the wavelength selective photoelectric conversion material and may have improved wavelength selectivity by combining the absorption spectrum of the wavelength selective photoelectric conversion material of the photoelectric conversion layer 330 and the controlled thickness of the buffer layer 335 as described above. Therefore, the sensor 300 may exhibit light absorption characteristics and photoelectric conversion characteristics in a narrower range, thereby further improving the sensitivity of the sensor 300.

The aforementioned sensor-embedded display panel 1000 may be applied to electronic devices such as various display devices. Electronic devices such as display devices may be applied to, for example, one or more of mobile phones, video phones, smart phones, smart pads, smart watches, digital cameras, tablet PCs, laptop PCs, notebook computers, computer monitors, wearable computers, televisions, digital broadcasting terminals, e-books, personal digital assistants (PDAs), portable multimedia player (PMP), enterprise digital assistant (EDA), head mounted display (HMD), vehicle navigation, Internet of Things (IoT), Internet of all things (IoE), drones, door locks, safes, automatic teller machines (ATM), security devices, medical devices, or automotive electronic components, but are not limited thereto.

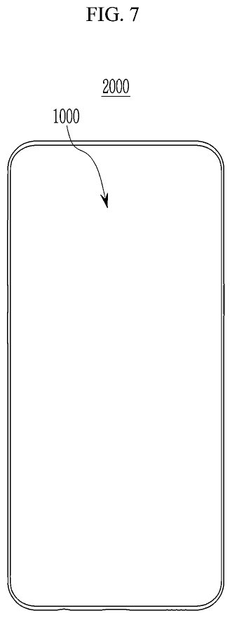

FIG. 7 is a schematic view illustrating an example of a smart phone as an electronic device according to an example embodiment.

Referring to FIG. 7, the electronic device 2000 according to some example embodiments may include the aforementioned sensor-embedded display panel 1000 which includes the sensor 300 on the whole or a part thereof, and thus a biometric recognition function may be performed on any part of the screen, and according to the user's selection, the biometric recognition function may be selectively performed only at a specific location where the biometric recognition function is required. The electronic device 2000 may include one or more passive devices (such as one or more resistors, capacitors, inductors, or memristors), and/or one or more active devices (such as one or more transistors or diodes).

An example of a method of recognizing the recognition target 40 in an electronic device 2000 such as a display device may include, for example, driving the first, second, and third light emitting elements 210, 220, and 230 and the sensor 300 of the sensor-embedded display panel 1000 to sense the light reflected from the recognition target 40 among the light emitted from the first, second, and/or third light emitting elements 210, 220, and 230, in the sensor 300; comparing the image of the recognition target 40 stored in advance with the image of the recognition target 40 sensed by the sensor 300; and judging the consistency of the compared images and if they match according to the determination that recognition of the recognition target 40 is completed, turning off the sensor 300, permitting user's access to the display device, and driving the sensor-embedded display panel 1000 to display an image.

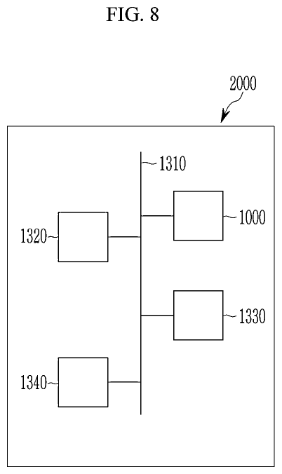

FIG. 8 is a schematic view illustrating an example of a configuration view of an electronic device according to some example embodiments.

Referring to FIG. 8, in addition to the aforementioned constituent elements, the electronic device 2000 may further include a bus 1310, a processor 1320, a memory 1330, and at least one additional device 1340. Information of the aforementioned sensor-embedded display panel 1000, processor 1320, memory 1330, and at least one additional device 1340 may be transmitted to each other through the bus 1310.

The processor 1320 may include one or more processing circuitry such as a hardware including logic circuits; a hardware/software combination such as processor-implemented software; or any combination thereof. For example, the processing circuitry may be a central processing unit (CPU), an arithmetic logic unit (ALU), a digital signal processor, a microcomputer, a field programmable gate array (FPGA), System-on-Chip (SoC), a programmable logic unit, a microprocessor, an application-specific integrated circuit (ASIC), and the like. As an example, the processing circuitry may include a non-transitory computer readable storage device. The processor 1320 may control, for example, a display operation of the sensor-embedded display panel 1000 or a sensing operation of the sensor 300.

The memory 1330 may be a non-transitory computer readable storage medium, such as, for example, as a solid state drive (SSD), and may store an instruction program, and the processor 1320 may perform a function related to the sensor-embedded display panel 1000 by executing the stored instruction program.

The at least one additional device 1340 may be one or more communication interfaces (e.g., wireless communication interfaces, wired interfaces), user interfaces (e.g., keyboard, mouse, buttons, etc.), power supply and/or power supply interfaces, or any combination thereof.

The units and/or modules described herein may be implemented using hardware constituent elements and software constituent elements. The units and/or modules described herein may include, may be included in, and/or may be implemented by one or more articles of processing circuitry such as a hardware including logic circuits; a hardware/software combination such as processor-implemented software; or any combination thereof. For example, the processing circuitry may be a central processing unit (CPU), an arithmetic logic unit (ALU), a digital signal processor, a microcomputer, a field programmable gate array (FPGA), System-on-Chip (SoC), a programmable logic unit, a microprocessor, an application-specific integrated circuit (ASIC), and the like. For example, the hardware constituent elements may include microphones, amplifiers, band pass filters, audio-to-digital converters, and processing devices. The processing device may be implemented using one or more hardware devices configured to perform and/or execute program code by performing arithmetic, logic, and input/output operations. The processing device may include a processor, a controller and an arithmetic logic unit, a digital signal processor, a microcomputer, a field programmable array, a programmable logic unit, a microprocessor, or any other device capable of responding to and executing instructions. The processing device may access, store, operate, process, and generate data in response to execution of an operating system (OS) and one or more software running on the operating system.

The software may include a computer program, a code, an instruction, or any combination thereof, and may transform a processing device for a special purpose by instructing and/or configuring the processing device independently or collectively to operate as desired. The software and data may be implemented permanently or temporarily as signal waves capable of providing or interpreting instructions or data to machines, parts, physical or virtual equipment, computer storage media or devices, or processing devices. The software may also be distributed over networked computer systems so that the software may be stored and executed in a distributed manner. The software and data may be stored by one or more non-transitory computer readable storage devices.

The method according to the foregoing example embodiments may be recorded in a non-transitory computer readable storage device including program instructions for implementing various operations of the aforementioned example embodiments. The storage device may also include program instructions, data files, data structures, and the like alone or in combination. The program instructions recorded in the storage device may be specially designed for the present embodiment or may be known to those skilled in computer software and available for use. Examples of non-transitory computer-readable storage devices may include magnetic media such as hard disks, floppy disks, and magnetic tapes; optical media such as CD-ROM discs, DVDs and/or blue-ray discs; magneto-optical media such as optical disks; and a hardware device configured to store and execute program instructions such as ROM, RAM, flash memory, and the like. The aforementioned device may be configured to operate as one or more software modules to perform the operations of the aforementioned example embodiments.

When the terms “about” or “substantially” are used in this specification in connection with a numerical value, it is intended that the associated numerical value includes a manufacturing or operational tolerance (e.g., +10%) around the stated numerical value. Moreover, when the words “generally” and “substantially” are used in connection with geometric shapes, it is intended that precision of the geometric shape is not required but that latitude for the shape is within the scope of the disclosure. Moreover, when the words “generally” and “substantially” are used in connection with material composition, it is intended that exactitude of the material is not required but that latitude for the material is within the scope of the disclosure.

Further, regardless of whether numerical values or shapes are modified as “about” or “substantially,” it will be understood that these values and shapes should be construed as including a manufacturing or operational tolerance (e.g., +10%) around the stated numerical values or shapes. Thus, while the term “same,” “identical,” or “equal” is used in description of example embodiments, it should be understood that some imprecisions may exist. Thus, when one element or one numerical value is referred to as being the same as another element or equal to another numerical value, it should be understood that an element or a numerical value is the same as another element or another numerical value within a desired manufacturing or operational tolerance range (e.g., +10%).

While example embodiments have been described in connection with what is presently considered to be practical example embodiments, it is to be understood that the invention is not limited to the disclosed example embodiments. On the contrary, it is intended to cover various modifications and equivalent arrangements included within the spirit and scope of the appended claims. Furthermore, example embodiments are not necessarily mutually exclusive with one another. For example, some example embodiments may include one or more features described with reference to one or more figures, and may also include one or more other features described with reference to one or more other figures.

What is claimed is:

1. A sensor-embedded display panel, the sensor-embedded display panel comprising:
a substrate,
a plurality of light emitting elements on the substrate, the plurality of light emitting elements configured to emit light of different wavelength spectra belonging to the visible light wavelength spectrum, and
a plurality of sensors on the substrate, the plurality of sensors being configured to selectively sense light of any one of a green wavelength spectrum and a red wavelength spectrum, wherein
the plurality of light emitting elements and the plurality of sensors are arranged in parallel along an in-plane direction of the substrate,
the plurality of light emitting elements and the plurality of sensors commonly comprise:
a common electrode configured to apply a common voltage,
a first common auxiliary layer under the common electrode, and
a second common auxiliary layer facing the first common auxiliary layer,
wherein each of the sensors comprises a photoelectric conversion layer and a buffer layer between the first common auxiliary layer and the second common auxiliary layer,
the photoelectric conversion layer comprises a first wavelength-selective photoelectric conversion material having a first maximum absorption wavelength in a wavelength range of greater than or equal to about 500 nm and less than or equal to about 600 nm, and a thickness of the buffer layer is greater than or equal to about 20 nm and less than or equal to about 50 nm, or
the photoelectric conversion layer comprises a second wavelength-selective photoelectric conversion material having a second maximum absorption wavelength in a wavelength range of greater than about 600 nm and less than or equal to about 750 nm, and a thickness of the buffer layer is greater than or equal to about 70 nm and less than or equal to about 110 nm.

2. The sensor-embedded display panel of claim 1, wherein the buffer layer is between the second common auxiliary layer and the photoelectric conversion layer.

3. The sensor-embedded display panel of claim 2, wherein
the second common auxiliary layer comprises a first hole transport material, and
the buffer layer comprises a second hole transport material.

4. The sensor-embedded display panel of claim 1, wherein
the photoelectric conversion layer comprises the first wavelength-selective photoelectric conversion material,
an extinction coefficient at the first maximum absorption wavelength of the first wavelength-selective photoelectric conversion material is greater than or equal to about 0.5, and
a refractive index at the first maximum absorption wavelength of the first wavelength-selective photoelectric conversion material is greater than or equal to about 2.0 and less than or equal to about 3.0.

5. The sensor-embedded display panel of claim 4, wherein a sum of thicknesses of the photoelectric conversion layer and the buffer layer is about 50 nm to about 100 nm.

6. The sensor-embedded display panel of claim 1, wherein
the photoelectric conversion layer comprises the second wavelength-selective photoelectric conversion material,
an extinction coefficient at the second maximum absorption wavelength of the second wavelength-selective photoelectric conversion material is greater than or equal to about 0.5, and
a refractive index at the second maximum absorption wavelength of the second wavelength-selective photoelectric conversion material is greater than or equal to about 2.0 and less than or equal to about 3.0.

7. The sensor-embedded display panel of claim 6, wherein a sum of thicknesses of the photoelectric conversion layer and the buffer layer is greater than or equal to about 100 nm and less than or equal to about 160 nm.

8. The sensor-embedded display panel of claim 1, wherein
each of the sensors further comprises a pixel electrode under the second common auxiliary layer, and
the pixel electrode includes a reflective electrode and the common electrode includes a semi-transmissive electrode.

9. The sensor-embedded display panel of claim 1, wherein a full width at half maximum (FWHM) of the absorption spectrum or EQE spectrum, respectively, of the sensor is narrower than FWHM of the respective absorption spectrum or EQE spectrum of the first wavelength-selective photoelectric conversion material or the second wavelength-selective photoelectric conversion material.

10. The sensor-embedded display panel of claim 1, wherein
the plurality of light emitting elements comprise:
a red light emitting element configured to emit light in a red wavelength spectrum,
a green light emitting element configured to emit light in a green wavelength spectrum, and
a blue light emitting element configured to emit light in a blue wavelength spectrum, and
wherein the sensor-embedded display panel comprises:
a plurality of red subpixels configured to display red and comprising the red light emitting element,
a plurality of green subpixels configured to display green and comprising the green light emitting element,
a plurality of blue subpixels configured to display blue and comprising the blue light emitting element, and
a plurality of sensor pixels including the sensor and configured to selectively sense light in the green wavelength spectrum.

11. The sensor-embedded display panel of claim 1, wherein
the plurality of light emitting element comprises:
a red light emitting element configured to emit light in a red wavelength spectrum,
a green light emitting element configured to emit light in a green wavelength spectrum, and
a blue light emitting element configured to emit light in a blue wavelength spectrum, and
wherein the sensor-embedded display panel comprises:
a plurality of red subpixels configured to display red and comprising the red light emitting element,
a plurality of green subpixels configured to display green and comprising the green light emitting element,
a plurality of blue subpixels configured to display blue and comprising the blue light emitting element, and
a plurality of sensor pixels including the sensor and configured to selectively sense light in the red wavelength spectrum.

12. A sensor-embedded display panel, the sensor-embedded display panel comprising unit pixels repeatedly arranged,
wherein each of the unit pixels comprises:
at least one red subpixel configured to display red and comprising a red light emitting element,
at least one green subpixel configured to display green and comprising a green light emitting element,
at least one blue subpixel configured to display blue and comprising a blue light emitting element, and
a sensor pixel comprising a sensor configured to selectively sense light in the red wavelength spectrum, and
wherein the sensor comprises:
a reflective electrode and a semi-transmissive electrode facing each other,
a photoelectric conversion layer between the reflective electrode and the semi-transmissive electrode, the photoelectric conversion layer comprising a wavelength-selective photoelectric conversion material having a maximum absorption wavelength in a wavelength region of greater than about 600 nm and less than or equal to about 750 nm, and
a buffer layer between the reflective electrode and the semi-transmissive electrode, the buffer layer having a thickness of greater than or equal to about 70 nm and less than or equal to about 110 nm.

13. The sensor-embedded display panel of claim 12, wherein
an extinction coefficient at the maximum absorption wavelength of the wavelength-selective photoelectric conversion material is greater than or equal to about 0.5, and
a refractive index at the maximum absorption wavelength of the wavelength-selective photoelectric conversion material is greater than or equal to about 2.0 and less than or equal to about 3.0.

14. The sensor-embedded display panel of claim 12, wherein
the red light emitting element, the green light emitting element, the blue light emitting element, and the sensor commonly comprise:
a first common auxiliary layer comprising an electron transport material, and
a second common auxiliary layer comprising a first hole transport material, and
wherein the buffer layer comprises a second hole transport material.

15. The sensor-embedded display panel of claim 14, wherein
each of the red light emitting element, the green light emitting element, the blue light emitting element, and the sensor comprises:
a common electrode configured to apply a common voltage to the red light emitting element, the green light emitting element, the blue light emitting element, and the sensor, and
a pixel electrode facing the common electrode, and
wherein the pixel electrode includes a reflective electrode and the common electrode includes a semi-transmissive electrode.

16. A sensor-embedded display panel, the sensor-embedded display panel comprising unit pixels repeatedly arranged,
wherein the unit pixels comprising:
at least one red subpixel configured to display red and comprising a red light emitting element,
at least one green subpixel configured to display green and comprising a green light emitting element,
at least one blue subpixel configured to display blue and comprising a blue light emitting element, and
a sensor pixel comprising a sensor configured to selectively sense light in the green wavelength spectrum, and
wherein the sensor comprises
a reflective electrode and a semi-transmissive electrode facing each other,
a photoelectric conversion layer between the reflective electrode and the semi-transmissive electrode, the photoelectric conversion layer comprising a wavelength-selective photoelectric conversion material having a maximum absorption wavelength in a wavelength region of greater than or equal to about 500 nm and less than or equal to about 600 nm, and
a buffer layer between the reflective electrode and the semi-transmissive electrode, the buffer layer having a thickness of greater than or equal to about 20 nm and less than or equal to about 50 nm.

17. The sensor-embedded display panel of claim 16, wherein
an extinction coefficient at the maximum absorption wavelength of the wavelength-selective photoelectric conversion material is greater than or equal to about 0.5, and
a refractive index at the maximum absorption wavelength of the wavelength-selective photoelectric conversion material is greater than or equal to about 2.0 and less than or equal to about 3.0.

18. The sensor-embedded display panel of claim 16, wherein
the red light emitting element, the green light emitting element, the blue light emitting element, and the sensor commonly comprise:
a first common auxiliary layer comprising an electron transport material, and
a second common auxiliary layer comprising a first hole transport material, and
wherein the buffer layer comprises a second hole transport material.

19. The sensor-embedded display panel of claim 18, wherein
each of the red light emitting element, the green light emitting element, the blue light emitting element, and the sensor comprises:
a common electrode configured to apply a common voltage to the red light emitting element, the green light emitting element, the blue light emitting element, and the sensor, and
a pixel electrode facing the common electrode, and
wherein the pixel electrode includes a reflective electrode and the common electrode includes a semi-transmissive electrode.

20. An electronic device comprising the sensor-embedded display panel of claim 1.
